(19) United States
(12) Patent Application Publication
(10) Pub. No.: US 2026/0047507 A1
(43) Pub. Date: Feb. 12, 2026

(54) SYSTEMS AND METHODS FOR MASSIVELY PARALLEL CHIP INTEGRATION

(71) Applicant: Advanced Micro Devices, Inc., Santa Clara, CA (US)

(72) Inventors: Deepak Vasant Kulkarni, Austin, TX (US); Raja Swaminathan, Austin, TX (US)

(73) Assignee: Advanced Micro Devices, Inc., Santa Clara, CA (US)

(21) Appl. No.: 18/324,884

(22) Filed: May 26, 2023

(51) Int. Cl. H01L 23/498; H01L 23/00; H01L 25/00; H01L 25/065; H01L 25/18; H10B 80/00

(52) U.S. Cl. CPC H01L 23/49833; H01L 24/08; H01L 24/16; H01L 25/18; H01L 25/50; H10B 80/00; H01L 23/49838; H01L 25/0652; H01L 2224/08225; H01L 2224/16225

(57) ABSTRACT

The disclosed interposer package can include a plurality of stacked circuit dies. The interposer package can additionally include a first interposer connected to the plurality of stacked circuit dies. The interposer package can also include a second interposer connected to the first interposer. Various other methods, systems, and computer-readable media are also disclosed.

### BACKGROUND

Traditional interposer packages having massively parallel chips (e.g., 3D chiplet stacks) and additional stacked circuit dies, such as high bandwidth memory (HBM), directly connect the 3D stacks and HBM in parallel to a silicon interposer using solder interconnects. Such monolithic silicon interposers are relatively expensive due to yield and reliability concerns of building one large interposer with four to five redistribution layers. Replacing such an interposer with system on integrated chip_horizontal (SolC_H) technology that uses hybrid bonding cannot incorporate additional stacked circuit dies that come from a different vendor and process node, such as HBMs.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for massively parallel chip integration.

FIG. 2 is a block diagram of an example interposer package having massively parallel chips and additional stacked circuit dies directly connected in parallel to a silicon interposer using solder interconnects.

FIG. 3 is a block diagram of an example interposer configured as a two stack interposer.

FIG. 4 is a block diagram of an example interposer configured as a two stack interposer.

FIG. 5 is a block diagram of an example interposer package having a two stack interposer.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for massively parallel chip integration. For example, by connecting a silicon interposer to a plurality of stacked circuit dies by hybrid bonding, connecting an additional interposer to the silicon interposer by one or more solder interconnects, and connecting an additional plurality of stacked circuit dies to the additional interposer by one or more additional solder interconnects, various limitations of traditional interposer packages can be overcome.

As noted above, traditional interposer packages having massively parallel chips (e.g., 3D chiplet stacks) and additional stacked circuit dies, such as high bandwidth memory (HBM), directly connect the 3D stacks and HBM in parallel to a silicon interposer using solder interconnects. This configuration of the interposer package imposes constraints on the pitch of the interconnects (e.g., 35 μm to 55 μm pitch) and the size of the silicon interposer (e.g., maximum 3.6 times reticle). These constraints limit the wiring density under the 3D chiplet stacks that require relatively high input/output and power delivery. This configuration of the interposer package additionally imposes constraints on the number of redistribution layers (e.g., four to five metal layers) in the silicon interposer. Another issue with the traditional interposer package configuration is that monolithic silicon interposers are relatively expensive due to yield and reliability concerns of building one large interposer with four to five redistribution layers. Replacing such an interposer with system on integrated chip_horizontal (SolC_H) technology that uses hybrid bonding is not an option because such an interposer cannot incorporate additional stacked circuit dies that come from a different vendor and process node, such as HBMs.

The disclosed two-stack interposer can connect to additional stacked circuit dies that come from a different vendor and process node while increasing the wiring density under the 3D chiplet stacks that require relatively high input/output and power delivery. These benefits can be achieved by using solder interconnects for the additional interposer and hybrid bonding for connection of the 3D chiplet stacks to the silicon interposer. Rather than resulting in a more expensive interposer, cost can be decreased by using an organic interposer or a glass interposer for the additional interposer. Further advantages arise in the ability to extend the size of the additional interposer beyond four times reticle, decrease pitch of the hybrid bonds below nine micrometers in regions of interest, and increase the redistribution layer count in a range of six to ten metal layers.

In one example, an interposer package includes a plurality of stacked circuit dies, a first interposer connected to the plurality of stacked circuit dies, and a second interposer connected to the first interposer.

Another example can be the previously described interposer package, further including an additional plurality of stacked circuit dies connected to the second interposer.

Another example can be any of the previously described interposer packages, wherein the additional plurality of stacked circuit dies is connected to the second interposer by one or more solder interconnects.

Another example can be any of the previously described interposer packages, wherein the additional plurality of stacked circuit dies corresponds to at least one high bandwidth memory stack.

Another example can be any of the previously described interposer packages, wherein the first interposer is connected to the plurality of stacked circuit dies by hybrid bonding.

Another example can be any of the previously described interposer packages, wherein the first interposer is made of silicon.

Another example can be any of the previously described interposer packages, wherein the first interposer has a hybrid bond pitch less than nine micrometers.

Another example can be any of the previously described interposer packages, wherein the first interposer includes a redistribution layer line/space of 0.4 micrometers/0.4 micrometers.

Another example can be any of the previously described interposer packages, wherein a total number of redistribution layers provided by the first interposer and the second interposer is greater than five.

Another example can be any of the previously described interposer packages, wherein the second interposer is connected to the first interposer by one or more solder interconnects.

Another example can be any of the previously described interposer packages, wherein the second interposer is made of at least one of organic material or glass.

Another example can be any of the previously described interposer packages, wherein a size of the second interposer is greater than four times a reticle area of a photomask of a lithography tool.

In one example, an interposer includes a first interposer attached by hybrid bonding to a plurality of stacked circuit dies and a second interposer attached by solder interconnects to the first interposer, wherein the second interposer is attachable by one or more additional solder interconnects to an additional plurality of stacked circuit dies.

Another example can be the previously described interposer, wherein at least one of the first interposer corresponds to a silicon interposer, the second interposer corresponds to at least one of an organic interposer or a glass interposer, or the additional plurality of stacked circuit dies includes at least one high bandwidth memory stack.

In one example, a method can include connecting a silicon interposer to a plurality of stacked circuit dies by hybrid bonding, connecting an additional interposer to the silicon interposer by one or more solder interconnects, and connecting an additional plurality of stacked circuit dies to the additional interposer by one or more additional solder interconnects.

Another example can be the previously described method, wherein the additional plurality of stacked circuit dies corresponds to at least one high bandwidth memory stack.

Another example can be any of the previously described methods, wherein the silicon interposer has a hybrid bond pitch less than nine micrometers.

Another example can be any of the previously described methods, wherein the silicon interposer includes a redistribution layer line/space of 0.4 micrometers/0.4 micrometers.

Another example can be any of the previously described methods, wherein a total number of redistribution layers provided by the silicon interposer and the additional interposer is greater than five.

Another example can be any of the previously described methods, wherein a size of the additional interposer is greater than four times a reticle area of a photomask of a lithography tool.

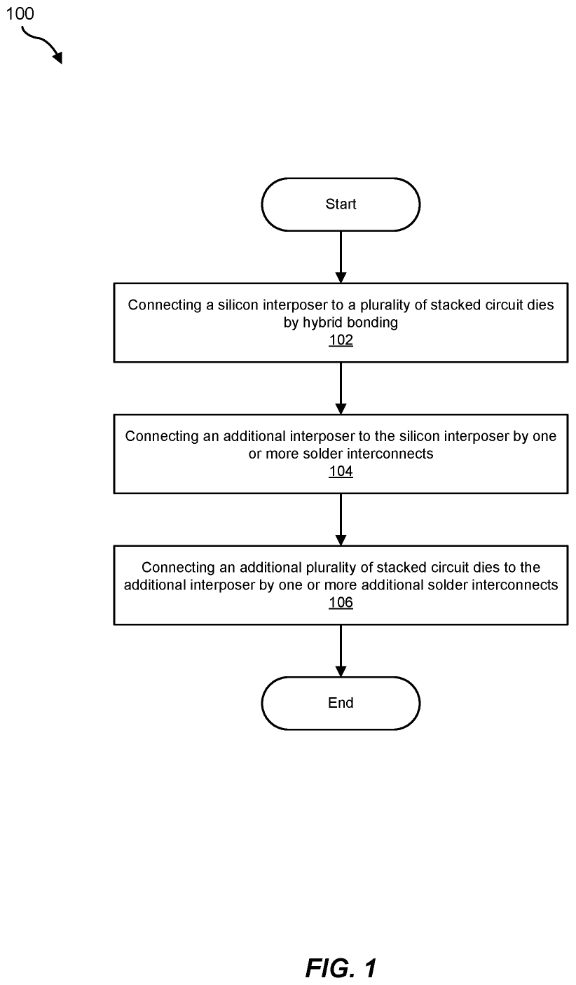

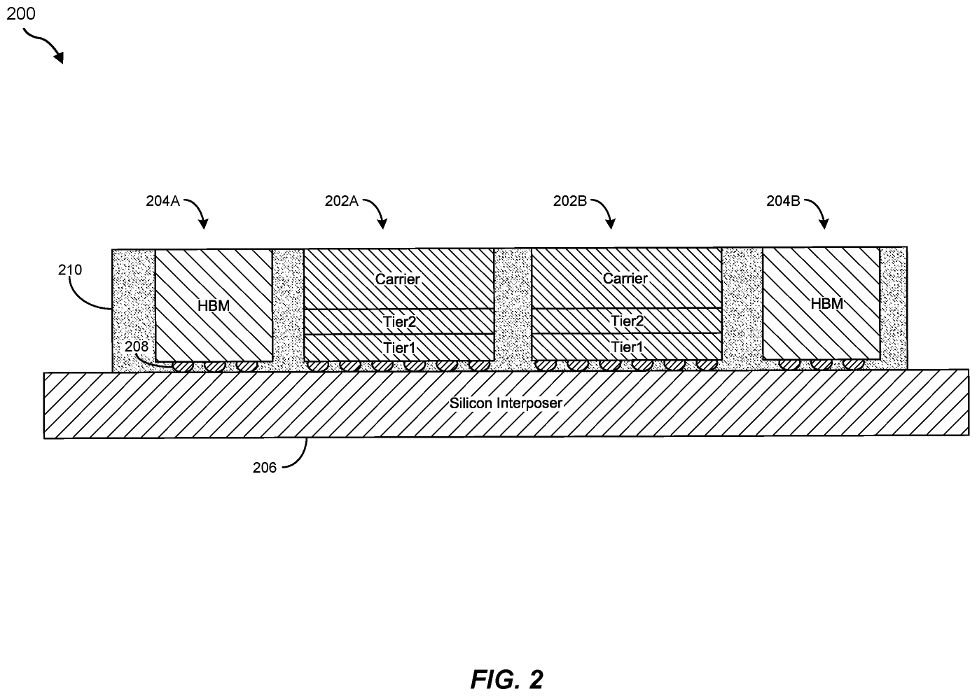

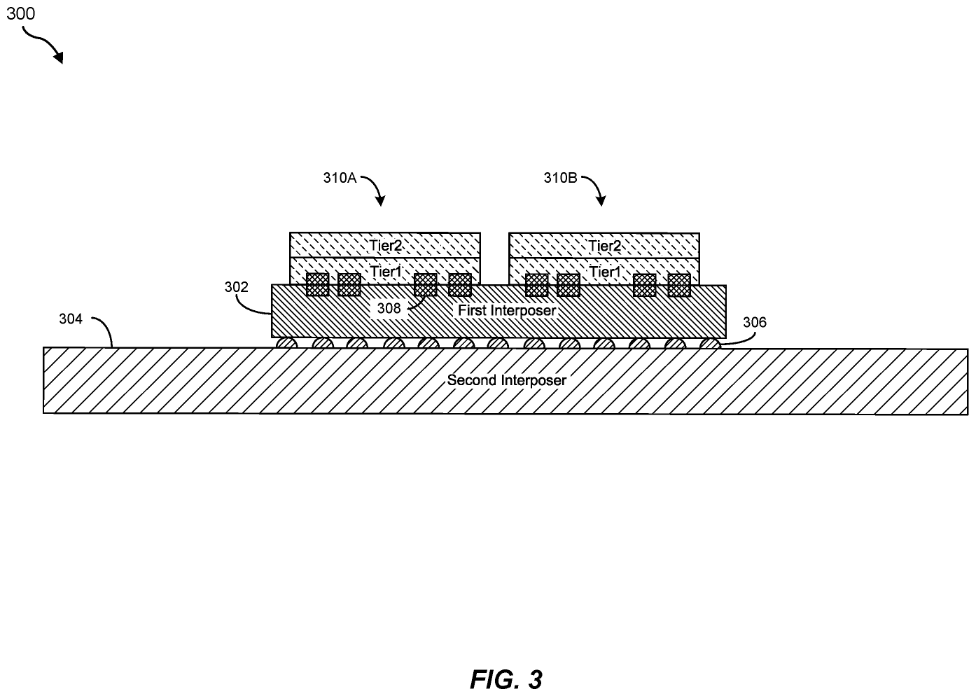

The following will provide, with reference to FIG. 1, detailed descriptions of example computer-implemented methods. In addition, detailed descriptions of example interposer packages will be provided in connection with FIGS. 2 and 3.

FIG. 1 is a flow diagram of an example computer-implemented method 100 for massively parallel chip integration. The steps shown in FIG. 1 can be performed by any suitable manufacturing process, including those using any suitable computer-executable code and/or computing system. In one example, each of the steps shown in FIG. 3 can represent an algorithm whose structure includes and/or is represented by multiple sub-steps, examples of which will be provided in greater detail below.

As illustrated in FIG. 1, step 102 can include connecting an interposer. For example, step 102 can include connecting a silicon interposer to a plurality of stacked circuit dies by hybrid bonding.

The term “interposer,” as used herein, can generally refer to an electrical interface routing between one socket or connection to another. For example, and without limitation, an interposer can spread a connection to a wider pitch or reroute a connection to a different connection. Types of interposers can include silicon interposers, silicon interposers that use system on integrated chip_horizontal (SolC_H) technology, organic interposers, and glass interposers. Unlike organic interposers and glass interposers, silicon interposers are composed of SiO2 or polymers and have a relatively higher cost (e.g., three times higher per wafer).

The term “hybrid bonding,” as used herein, can generally refer to forming a permanent bond that combines a dielectric bond with embedded metal (e.g., copper) to form interconnections. For example, and without limitation, hybrid bonding can allow for face-to-face connection of wafers or dies and provide both mechanical support and dense electrical interconnects. In some examples, hybrid bonding can be used for advanced 3D device stacking and heterogeneous integration applications. Hybrid bonding can deliver up to one-thousand times more connections than copper microbumps and reduce signal delay.

Step 102 can be performed in a variety of ways. For example, step 102 can include connecting a silicon interposer having a hybrid bond pitch less than nine micrometers. In some examples, step 102 can include connecting a silicon interposer that includes a redistribution layer line/space of 0.4 micrometers/0.4 micrometers.

Step 104 can include connecting an additional interposer. For example, step 102 can include connecting an additional interposer to the silicon interposer by one or more solder interconnects.

The term “solder interconnects,” as used herein, can generally refer to electrical connections made using a fusible metal alloy to create a permanent bond between metal workpieces. For example, and without limitation, solder interconnects can be made with solder bumps that are small spheres of solder (e.g., solder balls) that are bonded to contact areas or pads of semiconductor devices. Solder bumps can be used for face-down bonding.

Step 104 can be performed in a variety of ways. For example, step 104 can include connecting an additional interposer that is made of organic material or glass. In some examples, step 104 can include connecting an additional interposer that includes redistribution layers to a silicon interposer that also has redistribution layers. In some of these examples, a total number of redistribution layers provided by the silicon interposer and the additional interposer is greater than five (e.g., in a range of six to ten total redistribution layers). In some examples, step 104 can include connecting an additional interposer that has a size greater than four times (e.g., five times, six times, etc.) a reticle area of a photomask of a lithography tool.

Step 106 can include connecting an additional plurality of stacked circuit dies. For example, step 106 can include connecting an additional plurality of stacked circuit dies to the additional interposer by one or more additional solder interconnects.

The term “circuit die,” as used herein, can generally refer to a small block of semiconducting material on which a given functional circuit is fabricated. For example, and without limitation, integrated circuits can be produced in large batches on a single wafer of electronic-grade silicon (EGS) or other semiconductor through processes such as photolithography.

The term “stacked,” as used herein, can generally refer to 3D packaging. For example, and without limitation, stacked circuit dies can be configured according to 3D integration schemes that rely on traditional interconnection methods such as wire bonding and flip chip to achieve vertical stacking. Example types of 3D packages can include 3D system in package (3D SiP) and 3D wafer level package (3D WLP).

Step 106 can be performed in a variety of ways. For example, step 106 can include connecting an additional plurality of stacked circuit dies that corresponds to at least one high bandwidth memory stack.

The term “high bandwidth memory,” as used herein, can generally refer to a high-speed computer memory interface for 3D-stacked synchronous dynamic random-access memory (SDRAM). For example, and without limitation, high bandwidth memory can be used in conjunction with high-performance graphics accelerators, network devices, high-performance datacenter AI ASICs and FPGAs, and in some supercomputers.

Referring to FIG. 2, an example interposer package 200 can have massively parallel chips 202A and 202B (e.g., 3D chiplet stacks) and additional stacked circuit dies 204A and 204B (e.g., HBMs) directly connected in parallel to a silicon interposer 206 using solder interconnects 208. Interposer package 200 can also include mold material 210 (e.g., non-dielectric epoxy) provided between and/or beside the massively parallel chips 202A and 202B and additional stacked circuit dies 204A and 204B.

As noted above, this type of interposer package 200 imposes constraints on the pitch of the solder interconnects 208 (e.g., 35 μm to 55 μm pitch) and the size of the silicon interposer 206 (e.g., maximum 3.6 times reticle). These constraints limit the wiring density under the massively parallel chips 202A and 202B that require relatively high input/output and power delivery. This configuration of the interposer package 200 additionally imposes constraints on the number of redistribution layers (e.g., four to five metal layers) in the silicon interposer 206. Another issue with the configuration of interposer package 200 is that monolithic silicon interposers, such as silicon interposer 206, are relatively expensive due to yield and reliability concerns of building one large interposer with four to five redistribution layers. Replacing silicon interposer 206 with system on integrated chip_horizontal (SolC_H) technology that uses hybrid bonding is not an option because a SolC_H interposer cannot incorporate additional stacked circuit dies 204A and 204B that come from a different vendor and process node, such as HBMs.

Referring to FIG. 3, an example interposer 300 can be configured as a two-stack interposer. The interposer 300 can include a first interposer 302 attached by hybrid bonding 308 to a plurality of stacked circuit dies 310A and 310B and a second interposer 304 attached by solder interconnects 306 to the first interposer 302 (e.g., on a side opposite the plurality of stacked circuit dies 310A and 310B. The second interposer 304 can also be attachable by one or more additional solder interconnects to an additional plurality of stacked circuit dies (not shown). For example, the second interposer 304 can be attachable to the additional plurality of stacked circuit dies because it is wider and/or longer than the first interposer 302 as a result of having a size greater than four times (e.g., five or six times) a reticle area of a photomask of a lithography tool. This comparatively greater width and/or length can allow the additional plurality of stacked circuit dies to be positioned and attached on a same side of the second interposer 304 as the first interposer 302. As a result, the additional plurality of stacked circuit dies can be attached in parallel to the first interposer 302 and/or the plurality of stacked circuit dies 310A and 310B.

Interposer 300 can be configured in various ways. For example, the first interposer 302 can correspond to a silicon interposer (e.g., using SolC_H technology) and/or the second interposer 304 can correspond to an organic interposer and/or a glass interposer. In some examples, the additional plurality of stacked circuit dies can include at least one high bandwidth memory stack, or another type of stacked circuit die that comes from a different vendor and process node.

Parts of interposer 300 can have various characteristics. For example, the first interposer 302 can have a hybrid bond pitch less than nine micrometers in one or more area of interest. Additionally, the first interposer 302 can include a redistribution layer line/space of 0.4 micrometers/0.4 micrometers. Also, a total number of redistribution layers provided by the first interposer 302 and the second interposer 304 can be greater than five (e.g., in a range of six to ten redistribution layers). Further, a size of the second interposer 304 can be greater than four times (e.g., five or six times) a reticle area of a photomask of a lithography tool. In some implementations, data communication between different stacks of circuit dies of the plurality of stacked circuit dies 310A and 310B can be handled exclusively by the first interposer 302. In contrast, data communication between the plurality of stacked circuit dies 310A and 310B and the additional plurality of stacked circuit dies can be handled by the first interposer 302 and the second interposer 304 in combination.

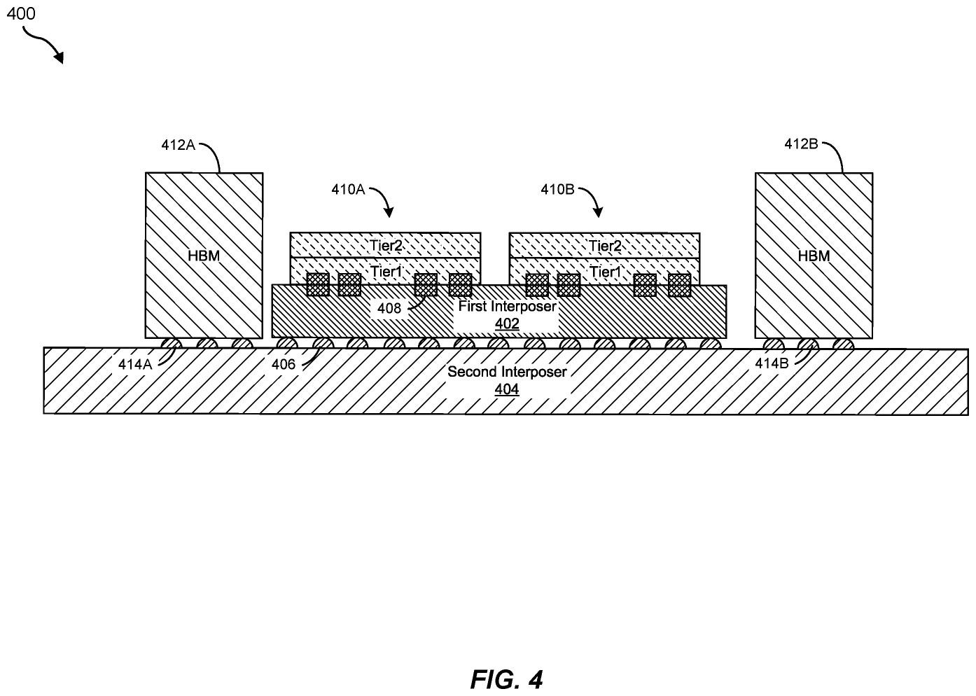

Referring to FIG. 4, an example interposer 400 can also be configured as a two-stack interposer. The interposer 400 can include a first interposer 402 attached by hybrid bonding 408 to a plurality of stacked circuit dies 410A and 410B and a second interposer 404 attached by solder interconnects 406 to the first interposer 402 (e.g., on a side opposite the plurality of stacked circuit dies 410A and 410B. The second interposer 404 can also be attached by one or more additional solder interconnects 414A and 414B to one or more additional pluralities of stacked circuit dies 412A and 412B. For example, the second interposer 404 can wider and/or longer than the first interposer 402 as a result of having a size greater than four times (e.g., five or six times) a reticle area of a photomask of a lithography tool. This comparatively greater width and/or length can allow the one or more additional pluralities of stacked circuit dies 412A and 412B to be positioned and attached on a same side of the second interposer 404 as the first interposer 402. As a result, the one or more additional pluralities of stacked circuit dies 412A and 412B can be attached in parallel to the first interposer 402 and/or the plurality of stacked circuit dies 410A and 410B.

Interposer 400 can be configured in various ways. For example, the first interposer 402 can correspond to a silicon interposer (e.g., using SolC_H technology) and/or the second interposer 404 can correspond to an organic interposer and/or a glass interposer. In some examples, the one or more additional pluralities of stacked circuit dies 412A and 412B can include at least one high bandwidth memory stack, or another type of stacked circuit die that comes from a different vendor and process node.

Parts of interposer 400 can have various characteristics. For example, the first interposer 402 can have a hybrid bond pitch less than nine micrometers in one or more area of interest. Additionally, the first interposer 402 can include a redistribution layer line/space of 0.4 micrometers/0.4 micrometers. Also, a total number of redistribution layers provided by the first interposer 402 and the second interposer 404 can be greater than five (e.g., in a range of six to ten redistribution layers). Further, a size of the second interposer 404 can be greater than four times (e.g., five or six times) a reticle area of a photomask of a lithography tool. In some implementations, data communication between different stacks of circuit dies of the plurality of stacked circuit dies 410A and 410B can be handled exclusively by the first interposer 402. In contrast, data communication between the plurality of stacked circuit dies 410A and 410B and the additional plurality of stacked circuit dies 412A and 412B can be handled by the first interposer 402 and the second interposer 404 in combination.

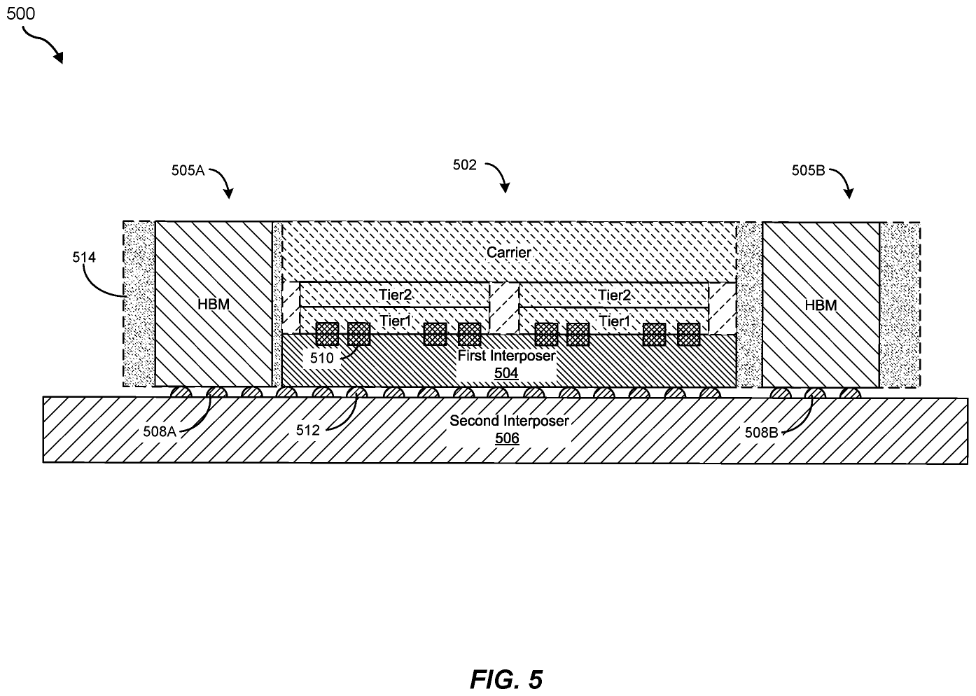

Referring to FIG. 5, an example interposer package 500 having a two stack interposer can include a plurality of stacked circuit dies 502 (e.g., 3D chiplet stacks) connected to a first interposer 504. Interposer package 500 can additionally include a second interposer 506 connected to the first interposer 504. In some examples, interposer package 500 can also include an additional plurality of stacked circuit dies 505A and 505B connected to the second interposer 506.

Parts of interposer package 500 can be connected in various ways. For example, the additional plurality of stacked circuit dies 504A and 504B can be connected to the second interposer 506 by one or more solder interconnects 508A and 508B. Additionally, the first interposer 504 can be connected to the plurality of stacked circuit dies 502 by hybrid bonding 510. Also, the second interposer 506 can be connected to the first interposer 504 by one or more solder interconnects 512.

Parts of interposer package 500 can vary in numerous ways. For example, the additional plurality of stacked circuit dies 505A and 505B can correspond to at least one high bandwidth memory stack. Additionally, the first interposer 504 can correspond to a silicon interposer (e.g., an SolC_H interposer). Also, the second interposer 506 can be made of organic material and/or glass.

Parts of interposer package 500 can have various characteristics. For example, the first interposer 504 can have a hybrid bond pitch less than nine micrometers in one or more area of interest. Additionally, the first interposer 504 can include a redistribution layer line/space of 0.4 micrometers/0.4 micrometers. Also, a total number of redistribution layers provided by the first interposer 504 and the second interposer 506 can be greater than five (e.g., in a range of six to ten redistribution layers). Further, a size of the second interposer 506 can be greater than four times (e.g., five or six times) a reticle area of a photomask of a lithography tool. In some implementations, data communication between different stacks of circuit dies plurality of stacked circuit dies 502 can be handled exclusively by the first interposer 504. In contrast, data communication between the plurality of stacked circuit dies 502 and the additional plurality of stacked circuit dies 505A and 505B can be handled by the first interposer 504 and the second interposer 506 in combination.

Interposer package 500 can have additional parts. For example, interposer package 500 can include mold material 514 (e.g., non-dielectric epoxy) provided between and/or beside the plurality of stacked circuit dies 502 and additional stacked circuit dies 504A and 504B. Additionally, massively parallel chips 502 can include tiered circuit dies and/or wafers arranged beneath a top carrier with gap filler (e.g., dielectric epoxy) provided between and/or beside the tiered circuit dies.

As set forth above, the disclosed systems and methods can use a hybrid bonded silicon interposer (SolC_H) to connect multiple 3D SoIC stacks that require high bandwidth area interconnect and use a second interposer made from organic material and/or glass, to connect to additional stacked circuit dies, such as one or more HBM stacks. This hybrid architecture can enable products with additional stacked circuit dies (e.g., HBMs), whereas current SolC_H architecture does not allow integration of additional stacked circuit dies.

The disclosed systems and methods exhibit numerous differences from traditional interposer packages. For example, the SolC_H interposer can use a hybrid bond pitch less than nine micrometers, which is significantly reduced compared to an approximate thirty-five micrometer pitch used by traditional interposers. Additionally, the organic and/or glass interposer can provide a looser pitch solder interconnect to connect the chip module (e.g., 3D SolC stacks) to the additional stacked circuit dies (e.g., HBMs). Also, the SolC_H interposer can achieve an aggressive line/space reduction to 0.4 micrometers/0.4 micrometers. Further, the two-stack interposer can achieve a redistribution layer count that is increased to six to ten metal layers by using 3D SoIC technology, which represents a significant increase compared to only four or five metal layers provided by traditional interposers. Further, a size of the disclosed interposer can be extended beyond a current limit of four times reticle stitching for the silicon interposer of the traditional interposer package. Further, higher wiring density can be provided under the 3D chiplet stacks that have higher input/output and power delivery interconnect requirements.

The disclosed systems and methods can exhibit numerous advantages over traditional interposer packages. For example, thicker redistribution layers can be employed in the organic and/or glass interposer, thus optimizing the SolC_H interposer for input/output and the organic and/or glass interposer for power delivery and HBM integration. Additionally, the disclosed interposer package can achieve higher bandwidth and lower energy for die to die interconnect. Also, the disclosed interposer package can achieve improved power delivery and lower voltage drop (IR drop) due to use of thick metal layers and copper pillars in the organic and/or glass interposer that is optimized for power delivery. Further, the disclosed interposer package can achieve higher performance for artificial intelligence products that are currently limited by interposer size less than four times (e.g., 3.6 times) a reticle area of a photomask of a lithography tool and, thus, cannot increase HBM count or increase die size. Finally, the disclosed interposer package can achieve reduced cost by using an organic and/or glass interposer and reducing a size of the SolC_H interposer compared to a size of the silicon interposer employed by traditional interposer packages.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An interposer package, comprising:
a plurality of stacked circuit dies;
a first interposer connected to the plurality of stacked circuit dies; and
a second interposer connected to the first interposer.

2. The interposer package of claim 1, further comprising an additional plurality of stacked circuit dies connected to the second interposer.

3. The interposer package of claim 2, wherein the additional plurality of stacked circuit dies is connected to the second interposer by one or more solder interconnects.

4. The interposer package of claim 2, wherein the additional plurality of stacked circuit dies corresponds to at least one high bandwidth memory stack.

5. The interposer package of claim 1, wherein the first interposer is connected to the plurality of stacked circuit dies by hybrid bonding.

6. The interposer package of claim 1, wherein the first interposer is made of silicon.

7. The interposer package of claim 1, wherein the first interposer has a hybrid bond pitch less than nine micrometers.

8. The interposer package of claim 1, wherein the first interposer includes a redistribution layer line/space of 0.4 micrometers/0.4 micrometers.

9. The interposer package of claim 1, wherein a total number of redistribution layers provided by the first interposer and the second interposer is greater than five.

10. The interposer package of claim 1, wherein the second interposer is connected to the first interposer by one or more solder interconnects.

11. The interposer package of claim 1, wherein the second interposer is made of at least one of organic material or glass.

12. The interposer package of claim 1, wherein a size of the second interposer is greater than four times a reticle area of a photomask of a lithography tool.

13. An interposer, comprising:
a first interposer attached by hybrid bonding to a plurality of stacked circuit dies; and
a second interposer attached by solder interconnects to the first interposer,
wherein the second interposer is attachable by one or more additional solder interconnects to an additional plurality of stacked circuit dies.

14. The interposer of claim 13, wherein at least one of:
the first interposer corresponds to a silicon interposer;
the second interposer corresponds to at least one of an organic interposer or a glass interposer; or
the additional plurality of stacked circuit dies includes at least one high bandwidth memory stack.

15. A method comprising:
connecting a silicon interposer to a plurality of stacked circuit dies by hybrid bonding;
connecting an additional interposer to the silicon interposer by one or more solder interconnects; and
connecting an additional plurality of stacked circuit dies to the additional interposer by one or more additional solder interconnects.

16. The method of claim 15, wherein the additional plurality of stacked circuit dies corresponds to at least one high bandwidth memory stack.

17. The method of claim 15, wherein the silicon interposer has a hybrid bond pitch less than nine micrometers.

18. The method of claim 15, wherein the silicon interposer includes a redistribution layer line/space of 0.4 micrometers/0.4 micrometers.

19. The method of claim 15, wherein a total number of redistribution layers provided by the silicon interposer and the additional interposer is greater than five.

20. The method of claim 15, wherein a size of the additional interposer is greater than four times a reticle area of a photomask of a lithography tool.
